(19) United States
(12) Patent Application Publication
(10) Pub. No.: US 2008/0197388 A1
(43) Pub. Date: Aug. 21, 2008

(54) Pixel structure of CMOS image sensor and method of forming the pixel structure

(75) Inventors: Jong-eun Park, Seongnam-si (KR); Keun-chan Yuk, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/010,809

(22) Filed: Jan. 30, 2008

(30) Foreign Application Priority Data
Feb. 21, 2007 (KR) 10-2007-0017536

(51) Int. Cl. H01L 27/146; H01L 21/8234

(52) U.S. Cl. 257/292; 438/70; 257/E27.134

(57) ABSTRACT

Provided is a pixel structure of a CMOS image sensor. The pixel structure may include a semiconductor substrate, a photo diode, and a color filter. The photo diode may have a trench structure formed in the semiconductor substrate. The color filter may be formed in the trench structure. The color filter may be formed by filling a material in the trench structure using a gap-fill process. The material in the trench structure may transmit light having a wavelength within a predetermined or given range. Because the color filter of the pixel structure of the CMOS image sensor may be formed in the photo diode having the afore-mentioned trench structure, the height of the pixel may be decreased, and the efficiency of the output signal and the color sensitivity may be increased.

### PRIORITY STATEMENT

This application claims priority under 35 U.S.C. § 119 to Korean Patent Application No. 2007-0017536, filed on Feb. 21, 2007, in the Korean Intellectual Property Office (KIPO), the entire contents of which are herein incorporated by reference.

### BACKGROUND

1. Field

Example embodiments relate to a pixel structure of a complementary metal-oxide semiconductor (CMOS) image sensor for improving color sensitivity and a method of forming the pixel structure of the CMOS image sensor.

2. Description of Related Art

A CMOS image sensor (CIS) is a device that converts a visual image into an electronic signal in order to display the image on a display device. A photo diode unit of the CMOS image sensor receives light and converts the light (e.g., an optical signal) into an electronic signal using photoelectric conversion. The CMOS image sensor transfers electrons generated by the photoelectric conversion to a floating diffusion node (FD) using a transfer gate (TG). The CMOS image sensor processes an image signal using the electric potential difference generated in the floating diffusion node.

The CMOS image sensor includes a photo diode region and a peripheral region. A photo diode is a photo detector that converts an optical signal into an electronic signal and forms a pixel.

FIG. 1 is a cross-sectional view illustrating a pixel structure of a conventional CMOS image sensor.

Referring to FIG. 1, the pixel structure includes photo diode regions and color filters (e.g., a red color filter 103 and a green color filter 121). FIGS. 1 and 2 illustrate a red color filter 103 and a green color filter 121 as the color filters. A photo diode is formed on a semiconductor substrate 109 (e.g., a Si substrate). The photo diode receives light through the color filter 103.

Light enters into the CMOS image sensor through a lens 101. Generally, a convex lens is used as the lens 101. The lens 101 condenses and sends the light to the color filter 103.

Each of the color filters 103 and 121 transmits light having a wavelength within a predetermined range. Light having a wavelength in the range from about 630 nm to 780 nm is transmitted through the red color filter (Red CF) 103. Light having a wavelength in the range from about 510 nm to about 550 nm is transmitted through the green color filter (Green CF) 121. Light having a wavelength in the range from about 460 nm to about 480 nm is transmitted through a blue color filter (not shown).

The photo diode regions include an N-type doped region 107, which is doped with an N-type impurity, and a P-type doped region 105, which is doped with a P-type impurity. Light transmitted through the color filters is converted into electronic signals in the photo diode regions.

In the conventional pixel structure illustrated in FIG. 1, a portion of light transmitted through the red color filter 103 is reflected from a shallow trench isolation (STI) 111. As such, scattering light is present due to the distance between the red color filter 103 and the Si substrate 109, thereby decreasing the sensitivity of the photo diode.

As an electronic device including the CMOS image sensor is miniaturized, the pixel size is reduced. Since the pixel size is reduced, a sectional area of the photo diode is also reduced. When the sectional area of the photo diode is reduced, the amount of light to be received is also reduced, and thus, the output signal of the photo diode may weaken. However, the amount of the output signal should be larger than a predetermined amount so as to obtain sufficient color contrast. That is, color contrast is better when the amount of light increases.

In the conventional pixel structure illustrated in FIG. 1, when the pixel size is reduced, the photo diode size is also reduced. Therefore, in the pixel structure illustrated in FIG. 1, when the pixel size is smaller, the strength of the output signal is reduced. As such, color contrast and sensitivity are not guaranteed.

FIG. 2 is a cross-sectional view illustrating another pixel structure of a conventional CMOS image sensor.

Referring to FIG. 2, a photo diode region of the pixel structure illustrated in FIG. 2 is formed in a trench structure. That is, a trench is formed using an etching process, and then a photo diode is formed in the trench. The sectional area of the photo diode can be increased by forming the photo diode into the trench structure as described above in comparison to that of a photo diode having the pixel structure illustrated in FIG. 1. Therefore, although the pixel size of an electronic device is reduced due to miniaturization, the sectional area of the photo diode of the electronic device can be increased by forming the photo diode in a trench structure. As a result, color contrast and sensitivity of the photo diode may be maintained.

The pixel structure illustrated in FIG. 2 is similar to that illustrated in FIG. 1. Thus, a detailed description of the similar elements is omitted.

In the pixel structure illustrated in FIG. 2, scattering light is present due to the distance between a red color filter 203 and a Si substrate 209, thereby decreasing the sensitivity of the photo diode.

Referring to FIG. 2, a portion of light transmitted through the red color filter 203 is reflected from a STI 211, and another portion of light transmitted through the red color filter 203 arrives at the photo diode region of a green color filter 221. Although the light transmitted through the red color filter 203 is red, the portion of light arriving at the photo diode region of the green color filter 221 may be considered as green light.

As described above, in the conventional pixel structures illustrated in FIGS. 1 and 2, scattering light is present due to the distance between the color filter and the Si substrate (or the distance between the color filter and the photo diode region). Thus, the strength of the output signal is reduced and the sensitivity of the photo diode is decreased.

### SUMMARY

Example embodiments provide a pixel structure of a complementary metal-oxide semiconductor (CMOS) image sensor for improving color sensitivity. Example embodiments also provide a method of forming a pixel structure of a CMOS image sensor for improving color sensitivity.

According to example embodiments, a pixel structure of a complementary metal-oxide semiconductor (CMOS) image sensor may include a semiconductor substrate, a photo diode having a trench structure in the semiconductor substrate, and a color filter in the trench structure. The color filter may be formed by filling a material in the trench structure using a gap-fill process. The material in the trench structure may transmit light having a wavelength within a desired, or alternatively, a predetermined range.

The color filter may transmit one of red, green, and blue colors, and may be formed of a heat-resistant material resistant to a temperature of about 200° C. or higher.

The pixel structure may further include an isolation layer formed at a side of the photo diode in a vertical direction in the substrate.

The pixel structure may further include a floating diffusion node spaced apart from the photo diode and formed on the upper portion of the semiconductor substrate. The floating diffusion node may receive the photocharge generated in the photo diode.

According to example embodiments, a method of forming a pixel structure of a CMOS image sensor may include forming a trench structure in the upper portion of a semiconductor substrate, forming a photo diode in the trench structure, and forming a color filter in the photo diode. The color filter may be formed by filling a material in the trench structure using a gap-fill process. The material in the trench structure may transmit light having a wavelength within a desired, or alternatively, a predetermined range.

The method may further include forming an isolation layer spaced apart from the photo diode in a vertical direction in the semiconductor substrate.

The forming of the isolation layer may be performed prior to or after the forming of the trench structure.

The color filter may be formed of a heat-resistant material resistant to a temperature of about 200° C. or higher.

### BRIEF DESCRIPTION OF THE DRAWINGS

Example embodiments will be more clearly understood from the following detailed description taken in conjunction with the accompanying drawings. FIGS. 1-7E represent non-limiting, example embodiments as described herein.

FIG. 1 is a cross-sectional view illustrating a pixel structure of a conventional complementary metal-oxide semiconductor (CMOS) image sensor;

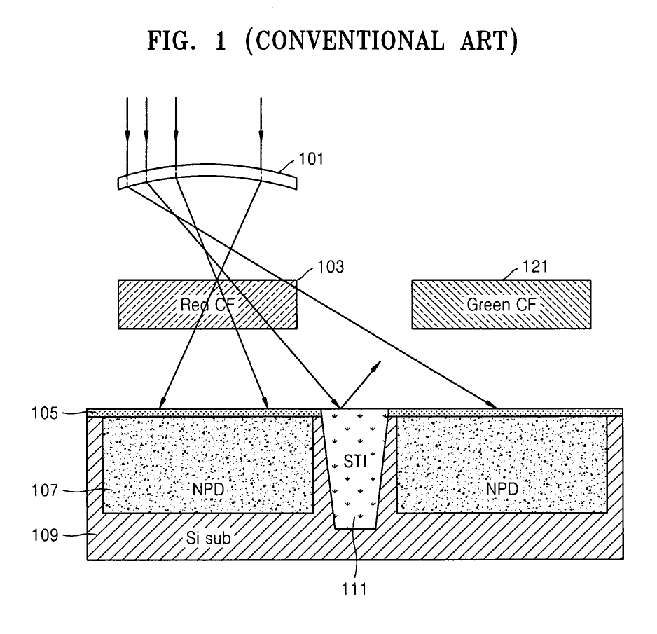

FIG. 2 is a cross-sectional view illustrating another pixel structure of a conventional CMOS image sensor;

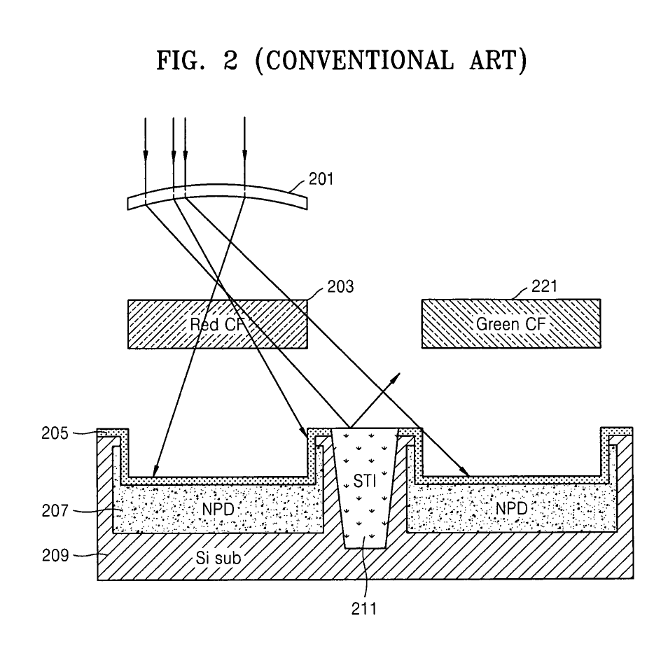

FIG. 3 is a circuit diagram illustrating a CMOS image sensor structure according to example embodiments;

FIG. 4A is a view illustrating a pixel of the CMOS image sensor illustrated in FIG. 3;

FIG. 4B is a horizontal sectional view illustrating a pixel structure of a CMOS image sensor according to example embodiments;

FIG. 5A is a cross-sectional view taken along line <a> of the pixel structure illustrated in FIG. 4B according to example embodiments;

FIG. 5B is a cross-sectional view taken along line <b> of the pixel structure illustrated in FIG. 4B according to example embodiments;

FIGS. 6A through 6E are cross-sectional views illustrating a method for forming a pixel structure of a CMOS image sensor according to an example embodiment; and

FIGS. 7A through 7E are cross-sectional views illustrating a method for forming a pixel structure of a CMOS image sensor according to an example embodiment.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

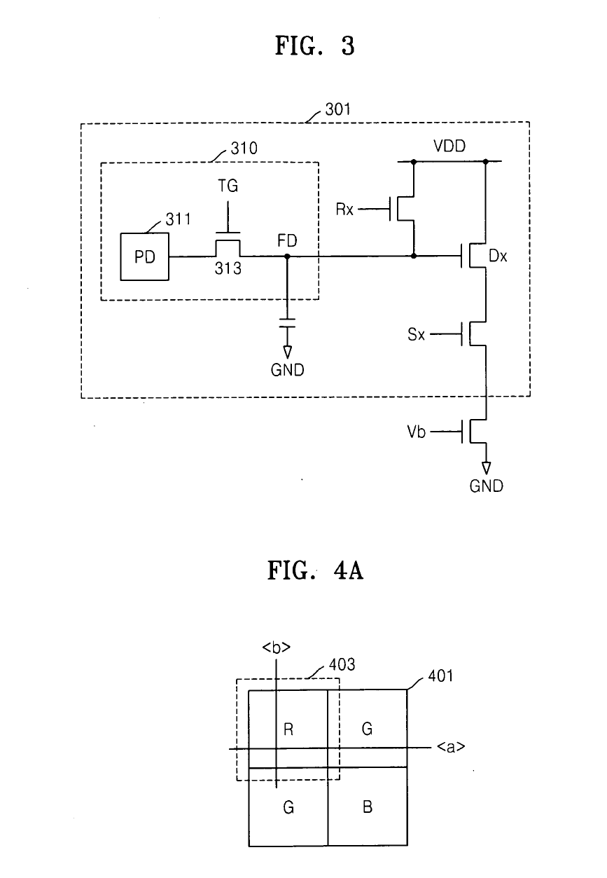

FIG. 3 is a circuit diagram illustrating a complementary metal-oxide semiconductor (CMOS) image sensor structure according to example embodiments.

Referring to FIG. 3, a unit pixel 301 of the CMOS image sensor may include a photo diode 311 and four NMOS gates (e.g., a transfer gate TG, a reset gate Rₓ, a driving gate Dₓ, and a select gate Sₓ). The transfer gate 313 may transfer a photocharge to a floating diffusion node FD. The reset gate Rₓ may reset the floating diffusion node FD by setting the electric potential of the floating diffusion node FD to a desired value and emitting an electric charge. The driving gate Dₓ may function as a source follower-buffer amplifier. The driving gate Dₓ may drive the current in response to the electric potential generated in the floating diffusion node FD. The select transistor may be switched in response to the gate voltage of the select gate Sₓ. A drain-source path may be formed between the source of the select transistor and the ground voltage GND of the select transistor.

Hereinafter, the pixel structure including the photo diode 311 and the transfer gate region 310 illustrated in FIG. 3 according to example embodiments will now be described in detail.

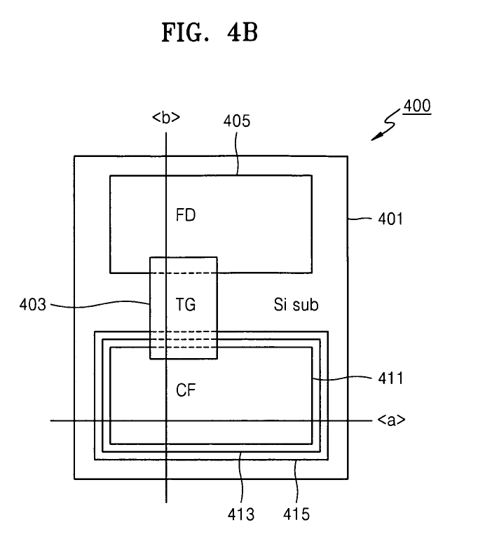

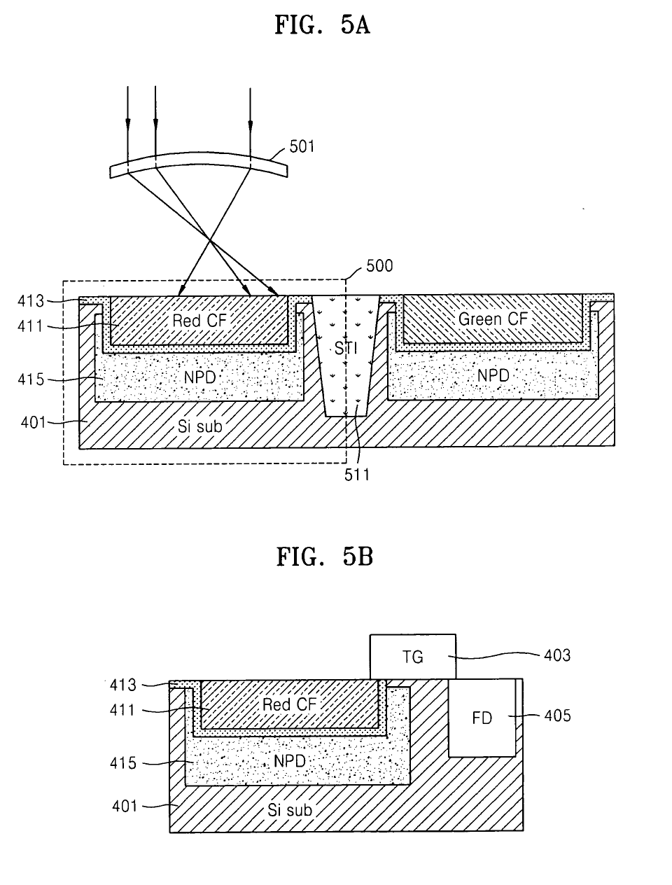

FIG. 4A is a view illustrating the pixel of the CMOS image sensor illustrated in FIG. 3.

Referring to FIG. 4A, a unit pixel may include a red region R, two green regions G, and a blue region B. Each region may include a photo diode region, a color filter, and a floating diffusion node FD. Each region may be defined based on the wavelength of light transmitted by the color filter thereof. Each region may have the same structure. A region illustrated in FIG. 4A will now be described in detail in reference to FIG. 4B.

FIG. 4B is a horizontal sectional view illustrating the pixel structure 400 of the CMOS image sensor according to example embodiments.

Referring to FIG. 4B, on a Si substrate 401, a region in the unit pixel may include photo diode regions 413 and 415, a floating diffusion node FD 405, and a transfer gate TG 403.

A color filter 411 may be formed in the photo diode regions 413 and 415 having a trench structure using a gap-fill process. The transfer gate 403 may be formed to cover portions of the color filter 411 and the floating diffusion node 405.

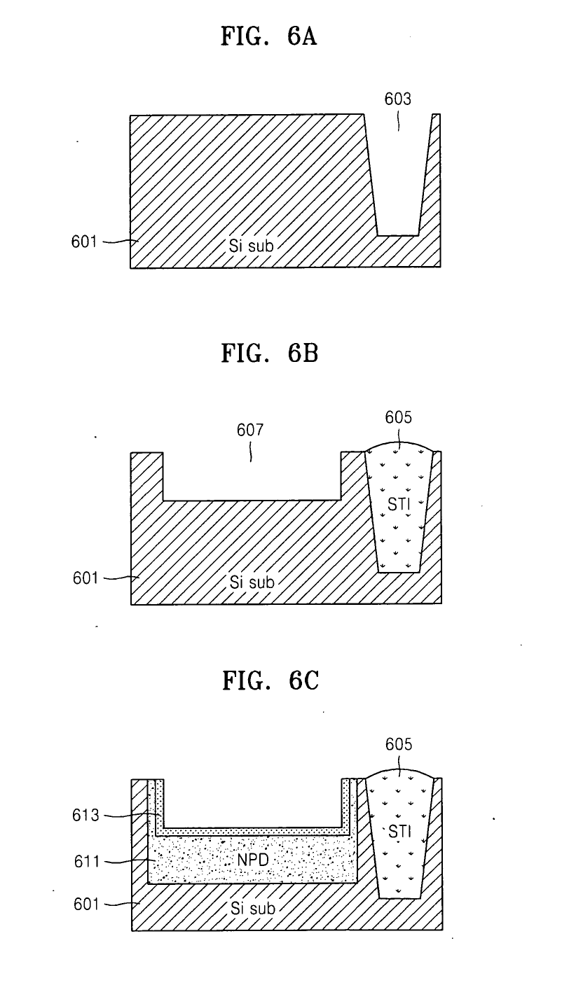

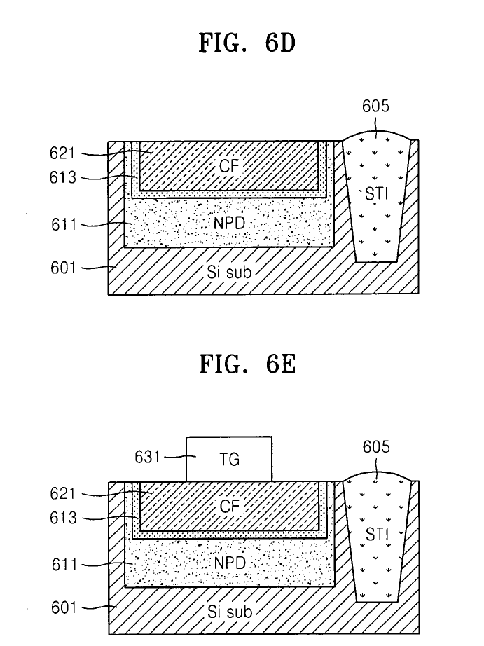

FIG. 5A is a cross-sectional view illustrating the pixel structure of FIG. 4B. In particular, FIG. 5A is a cross-sectional view taken along line <a> of the pixel structure illustrated in FIG. 4B.

Referring to FIG. 5A, a photo diode of the pixel structure according to example embodiments may be formed to have a trench structure in the Si substrate Si sub 401. A photo diode region 500 may include an N-type doped region 415, which may be doped with an N-type impurity and a P-type doped region 413, which may be doped with a P-type impurity. The N-type doped region 415 may have a trench structure obtained using an etching process, and the P-type doped region 413 may be formed on the N-type doped region 415 to obtain the photo diode having the trench structure.

The photo diode having the trench structure may include the color filter 411. The color filter 411 may be formed in the trench structure using a gap-fill process.

According to example embodiments, when a color filter is formed in a photo diode having a trench structure using a gap-fill process, scattering light, which is present due to the distance between the color filter and the Si substrate, may be reduced or eliminated. Therefore, introduced light may be more effectively collected, and an optical color mixing (e.g., a portion of light transmitted through a red color filter may arrive at a photo diode region of a green color filter) may be reduced or eliminated. As a result, the strength of the output signal and the sensitivity of the photo diode may be increased. In addition, the height of the pixel may be decreased, and thus, the size of the CMOS image sensor may be reduced.

The color filter may be formed of a heat-resistant material, and an inorganic material resistant to a temperature of about 200° C. or higher may be used. The heat-resistant material may be well known to those of ordinary skill in the art, and thus, a discussion thereof is omitted.

A shallow trench isolation STI 511 may be formed between the photo diode receiving red light and the photo diode receiving green light. The shallow trench isolation 511 may be formed of a dielectric layer so as to reduce or prevent signal interference between the photo diodes and the overflow of photocharges. The dielectric layer may be a silicon oxide layer. The dielectric layer may be formed using a STI method or a local oxidation of silicon (LOCOS) method.

FIG. 5B is a cross-sectional view illustrating the pixel structure of FIG. 4B. In particular, FIG. 5B is a cross-sectional view taken along line <b> of the pixel structure illustrated in FIG. 4B.

Referring to FIG. 5B, the floating diffusion node 405 may be spaced apart from the photo diode region 500. When a voltage is applied to the transfer gate 403 (thereby forming a channel), the transfer gate 403 may transfer the photocharge collected on the photo diode region 500 to the floating diffusion node 405.

The transfer gate 403 may be formed from a portion of the upper region of the photo diode region 500 to a portion of the upper region of the floating diffusion node 405. When the voltage is applied to the transfer gate 403, a channel may be formed between the photo diode region 500 and the floating diffusion node 405.

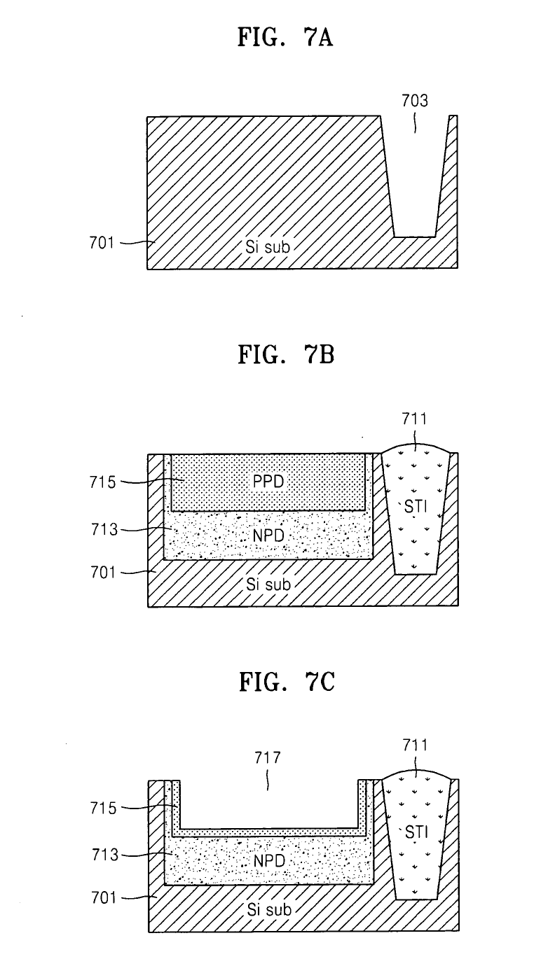

FIGS. 6A through 6E are cross-sectional views illustrating a method for forming a pixel structure of a CMOS image sensor according to an example embodiment.

Referring to FIG. 6A, a Si substrate 601 may be prepared as a semiconductor substrate. A trench 603 having a higher aspect ratio may be formed in the Si substrate 601 so as to form a shallow trench isolation. The trench 603 for a shallow trench isolation may be formed using a physical etching process or a chemical etching process.

Referring to FIG. 6B, a shallow trench isolation STI 605 may be formed by filling an oxide in the trench 603. The filling of the oxide may be performed using a common deposition process. For example, a chemical vapor deposition (CVD) forming a silicon oxide may be used. A trench structure 607 may then be formed using a common etching process.

Referring to FIG. 6C, a photo diode may be formed in the trench structure 607. A N-type doped region 611 may then be formed. Then, a P-type doped region 613 may be formed on the N-type doped region 611. The N-type and P-type doped regions 611 and 613 may be doped with N-type and P-type impurities, respectively, using an ion implantation process.

Referring to FIG. 6D, a color filter 621 may be formed on the photo diode formed in the trench structure 607. The color filter 621 may be formed by a gap-fill process.

Referring to FIG. 6E, a transfer gate 631 may be formed on the Si substrate 601 so as to connect portions of the upper regions of the photo diode and color filter 621 to a portion of the upper regions of a floating diffusion node.

Accordingly, the forming of a pixel structure of the CMOS image sensor according to example embodiments may then be completed.

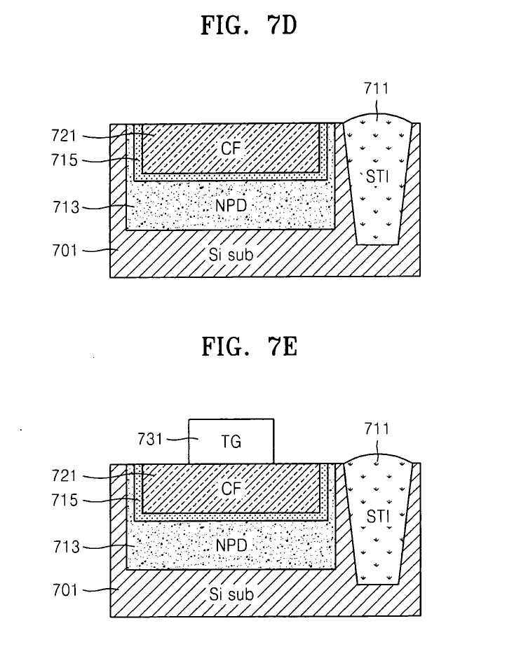

FIGS. 7A through 7E are cross-sectional views illustrating a method for forming a pixel structure of a CMOS image sensor according to an example embodiment.

Referring to FIG. 7A, a Si substrate 701 may be prepared as a semiconductor substrate. A trench 703 may then be formed using an etching process so as to form a shallow trench isolation STI 711 therein.

Referring to FIG. 7B, a photo diode may be formed in the Si substrate 701. In order to form the photo diode, the Si substrate 701 may be doped with a N-type impurity to form a N-type doped region 713. Then, the upper portion of the N-type doped region 713 may be doped with a P-type impurity to form a P-type doped region 715.

Referring to FIG. 7C, a trench structure 717 may be formed by etching the inside of the photo diode. The trench structure 717 may be formed using a photo lithography process (e.g., photo resist (PR) coating, exposing, stripping, and etching, sequentially).

Referring to FIG. 7D, the trench structure 717 of the photo diode may be filled with a color filter 721. The color filter 721 may be formed using a gap-fill process.

Referring to FIG. 7E, a transfer gate 731 may be formed on the Si substrate 701 so as to connect portions of the upper regions of the photo diode and color filter 721 to a portion of the upper region of a floating diffusion node.

As described above, a color filter of a pixel structure of the CMOS image sensor may be formed in a photo diode having a trench structure according to example embodiments. Moreover, the color filter may be formed in the photo diode having the trench structure using a method of forming the pixel structure of the CMOS image sensor according to example embodiments. Therefore, the height of the pixel may be decreased, and the efficiency of the output signal and the color sensitivity may be increased.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A pixel structure of a complementary metal-oxide semiconductor (CMOS) image sensor, the pixel structure comprising:
a semiconductor substrate;
a photo diode having a trench structure in the semiconductor substrate; and
a color filter in the trench structure, the color filter being formed using a gap-fill process by filling in the trench structure with a material that transmits light having a wavelength within a range.

2. The pixel structure of claim 1, wherein the color filter transmits one of red, green, and blue colors.

3. The pixel structure of claim 1, wherein the color filter is formed of a heat-resistant material that is resistant to a temperature of about 200° C. or higher.

4. The pixel structure of claim 1, further comprising:
an isolation layer at a side of the photo diode in a vertical direction in the substrate.

5. The pixel structure of claim 1, wherein the photo diode comprises:
a N-type doped region formed in an upper portion of the semiconductor substrate to a first depth by doping with a N-type impurity; and
a P-type doped region formed in an upper portion of the semiconductor substrate to a second depth by doping with a P-type impurity, the second depth being less than the first depth.

6. The pixel structure of claim 5, wherein the color filter is formed in the trench structure by a gap-fill process after forming the trench structure in the upper portion of the semiconductor substrate to a third depth, the third depth being less than the second depth.

7. The pixel structure of claim 1, further comprising:
a floating diffusion node on an upper portion of the semiconductor substrate and spaced apart from the photo diode, wherein the floating diffusion node receives a photocharge generated in the photo diode.

8. The pixel structure of claim 7, further comprising:
a transfer gate formed from a portion of an upper side of the photo diode to a portion of an upper side of the floating diffusion node.

9. The pixel structure of claim 4, wherein the semiconductor substrate is slightly doped with a N-type impurity, and the isolation layer has a shallow trench isolation (STI) structure or a local oxidation of silicon (LOCOS) structure.

10. A method of forming a pixel structure of a CMOS image sensor, the method comprising:
forming a photo diode having a trench structure in a semiconductor substrate; and
forming a color filter in the trench structure, the color filter being formed using a gap-fill process by filling in the trench structure with a material that transmits light having a wavelength within a range.

11. The method of claim 10, further comprising:
forming the trench structure in an upper portion of the semiconductor substrate to form the photodiode;
forming the photo diode in the trench structure; and
forming the color filter in the photo diode.

12. The method of claim 10, further comprising:
forming the photo diode in an upper region of the semiconductor substrate; and
forming the trench structure in the photo diode.

13. The method of claim 11, further comprising:
forming an isolation layer spaced apart from the photo diode in a vertical direction in the semiconductor substrate.

14. The method of claim 13, wherein the forming of the isolation layer is performed prior to or after the forming of the trench structure.

15. The method of claim 10, wherein the color filter is formed of a heat-resistant material that is resistant to a temperature of about 200° C. or higher.

16. The method of claim 10, wherein the color filter transmits one of red, green, and blue colors.

17. The method of claim 10, wherein the forming of the photo diode comprises:
forming a N-type doped region in an upper portion of the semiconductor substrate to a first depth by doping with a N-type impurity; and
forming a P-type doped region in an upper portion of the semiconductor substrate to a second depth by doping with a P-type impurity, the second depth being less than the first depth.

18. The method of claim 17, wherein the trench structure is formed in the upper portion of the semiconductor substrate to a third depth, and the color filter is formed in the trench structure by a gap-fill process, the third depth being less than the second depth.

19. The method of claim 10, further comprising:
forming of a floating diffusion node on an upper portion of the semiconductor substrate to be spaced apart from the photo diode, wherein the floating diffusion node receives a photocharge generated in the photo diode.

20. The method of claim 19, further comprising:
forming a transfer gate from a portion of an upper region of the photo diode to a portion of an upper region of the floating diffusion node.

21. The method of claim 13, wherein the semiconductor substrate is slightly doped with a N-type impurity, and the isolation layer has a shallow trench isolation (STI) or a local oxidation of silicon (LOCOS) structure.
